(19) United States
(12) Patent Application Publication
(10) Pub. No.: US 2023/0411447 A1
(43) Pub. Date: Dec. 21, 2023

(54) SEMICONDUCTOR DEVICE COMPRISING A LATERAL SUPER JUNCTION FIELD EFFECT TRANSISTOR

(71) Applicant: K. EKLUND INNOVATION, Uppsala (SE)

(72) Inventors: Klas-Håkan EKLUND, Uppsala (SE); Lars VESTLING, Södertälje (SE)

(21) Appl. No.: 17/845,715

(22) Filed: Jun. 21, 2022

(51) Int. Cl. H01L 29/06; H01L 29/49; H01L 29/78

(52) U.S. Cl. CPC H01L 29/0634; H01L 29/0646; H01L 29/4983; H01L 29/7825

(57) ABSTRACT

Disclosed is a semiconductor device, including: a substrate of a first conductivity type that is a base for the semiconductor device; a high voltage junction field effect transistor, JFET, over the substrate, wherein the JFET including parallel conductive layers; and a first conductive layer of the second conductivity type of the parallel conductive layers stretching over the substrate. On top of the first conductive layer of the second conductivity type are arranged layers forming the parallel conductive layers with channels formed by doped epitaxial layers of the second conductivity type with gate layers of the first conductivity type on both sides thereof; wherein at least one conductive layer of the first conductivity type above a lowermost conductive layer of the first conductive type is included of consecutive regions with different lengths and distances between each of the regions and the deep polycrystalline trenches of the second conductivity type.

### BACKGROUND OF THE INVENTION

### Field of the Invention

The present invention relates to a semiconductor device comprising a lateral superjunction field effect transistor, JFET, that can be implemented by placing a plurality of alternating n- and p-type layers on top of each other and connecting them in parallel.

### Description of the Related Art

Such devices have previously been described in many patent documents, e.g. in U.S. Pat. No. 11,031,480 B2, US 2019/0198609 A1, US 2017/0222043 A1, and US 2011/0127606 A1.

The stack of alternating n- and p-layers will, if they are matched in charge, completely deplete each other and a uniform electric field can be formed in the material with almost optimal use of the material in terms of breakdown voltage.

However, in the on-state, when the n-layer should conduct a current, the p-layers that are connected to ground will deplete the n-layers and effectively limit the maximum current that can be achieved.

### SUMMARY OF THE INVENTION

The object of the present invention is to reduce the above drawbacks and to obtaining a higher current through the device.

This object is obtained by the device according to the present invention, where at least one conductive layer of the first conductivity type (p2-p5) above a lowermost conductive layer of the first conductive type is comprised of consecutive areas with different lengths and distances between each of the areas and the deep polycrystalline trenches of the second conductivity type.

Further improvements can be obtained through the devices defined in the dependent claims.

### BRIEF DESCRIPTION OF THE DRAWINGS

The invention will now be explained with the help of a couple of non-limiting embodiments of a semiconductor device, focusing on the JFET part as shown on the accompanying drawings, in which:

FIG. 1 shows a first embodiment of the invention,

FIG. 2 shows a second embodiment of a further development of the invention,

FIG. 3 shows a third embodiment of the invention, and

FIG. 4 shows a fourth embodiment of the invention.

### DESCRIPTION OF THE PREFERRED EMBODIMENTS

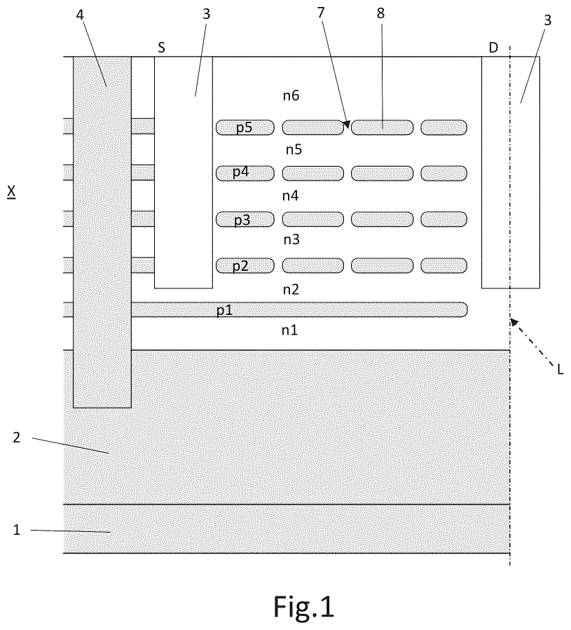

FIG. 1 shows the invention, starting with a highly doped substrate 1 of first conductivity type which is connected to a grounded back contact. On the substrate is a thick, low-doped layer 2 of first conductivity type epitaxially grown. The thickness of the epitaxial layer should be large enough to support the breakdown voltage of the device, for a device with a breakdown voltage of 650V, the thickness could for example be 60 μm and the doping 10¹⁴ cm⁻³. On the substrate a layer of second conductivity type is epitaxially grown n1, the thickness could for example be 7 μm and the doping 3×10¹⁴ cm⁻³. On the epitaxial layer n1 is an implantation mask placed, and an ion implantation is done forming a masked layer p1 of first conductivity type. The resulting charge in the layer should be about 2×10¹² cm⁻².

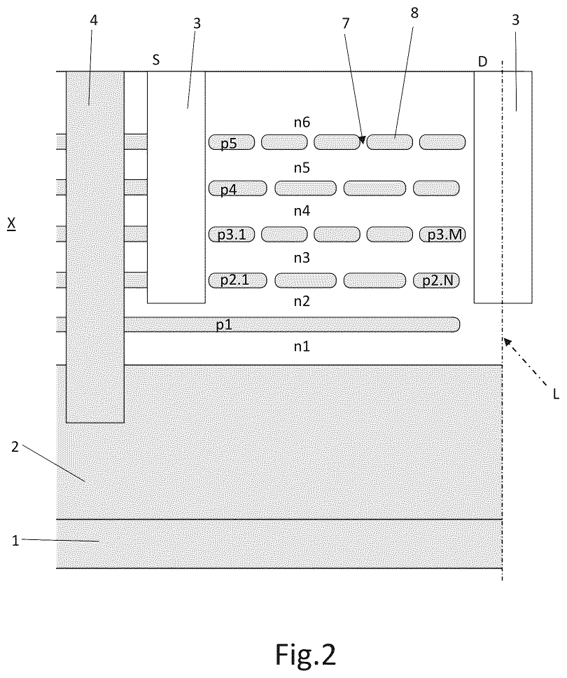

On top of the structure is now an epitaxial layer of second conductivity type n2 placed and a first gate of first conductivity type p2 is implanted through the openings in a mask. The thickness of the epitaxial layer is for example 2 m and the resulting charge in the layer should be about 2×10¹² cm⁻². The mask will divide the first gate in N different regions 8, where N for example is 4, with a distance 7 between the regions 8 of for example 0.3 μm, as shown in FIG. 1. The leftmost region p2.1 (shown in FIG. 2) is connected to ground as described in for example U.S. Pat. No. 11,031,480 B2; US 2019/0198609 A1; and US 2017/0222043 A1.

The other regions p2.2-p2.N (shown in FIG. 2) will be isolated from each other and are initially floating and this allows them to take a higher voltage when the drain voltage is increased. When the regions have a higher voltage than ground voltage the depletion will be smaller, and this will allow the saturation current in the channel to be higher.

The layers n3 and p3 are created in the same way as n2 and p2 with the same mask, the same thickness and doping levels. This is the repeated upwards as demonstrated in several earlier publications, e.g., the initially cited four patent documents.

From the surface deep trenches are etched and then filled with highly doped silicon, the width of the trenches is for example 3 m. Shown in FIG. 1 are two filled trenches 3 that are of second conductivity type and connecting the channels of second conductivity type n2-n6. A filled trench 4 of first conductivity type is used to connect the layers of first conductivity type p1-p5. If the number of layers of first conductivity type is five as shown in the figure, the depth of the trench 4 of first conductivity type is about 20 am and the depth of the trenches 3 of second conductivity type is about 10 μm. The gates p2-p5 are connected to ground in the third dimension, for example by making interruptions in the source trench as demonstrated in U.S. Pat. No. 11,031,480 B2, or by making filled trench pillars of first conductivity type as shown by US 2019/0198609 A1; or US 2017/0222043 A1.

A semiconductor device according to the invention can be combined with a further isolated region X arranged over the substrate, comprising logics and analogue control functions, isolated with deep polycrystalline trenches of the first conductivity type on both sides thereof, to the left of the parts shown in the figure. Such a semiconductor device is e.g. described in U.S. Pat. No. 11,031,480 B2.

The whole structure is mirrored around the line of symmetry L which allows for high voltage on the drain trench.

FIG. 2. shows a variation of FIG. 1 where the layers of first conductivity type p2-p5 are not the same. Here two layers, p2, p4, are divided into N regions 8 as shown previously, for example N=4. Layers p3, p5 are created using a different mask and are divided into M regions 8, where M is different from N, for example M=5. The distance 7 between the regions is for example 0.3 μm. When the layers are different, they will overlap each other and this will make the transition from off-state to on-state quicker and potentially increase performance. The length of the regions is preferably about 5 m.

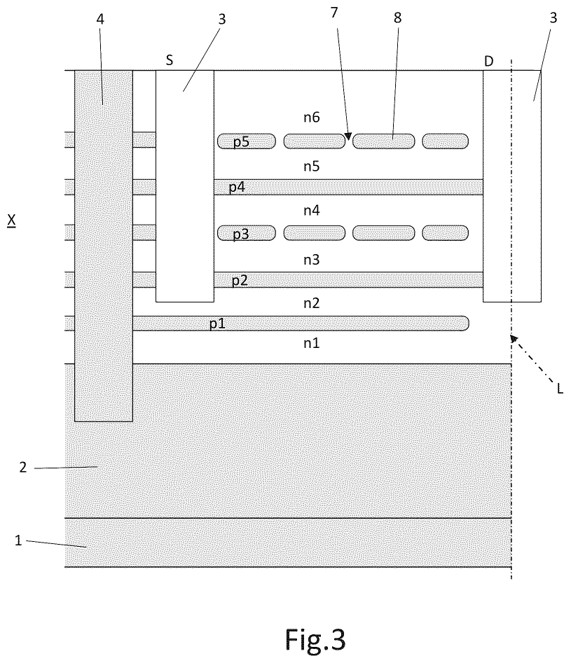

FIG. 3. shows a variation of FIG. 2 where two of the layers of first conductivity type p2 and p4, only have one region, N=1, that extends over the entire drift region. The layers p2 and p4 are consequently consecutive layers stretching between the deep polycrystalline trenches 3 of the second conductivity type. This can be made using a mask with only one region or by excluding the mask. Layers p3 and p5 are divided into M regions 8 as before, e.g., M=5. This will increase the transition speed further, compared to FIG. 2, but it will also affect the maximum current negatively.

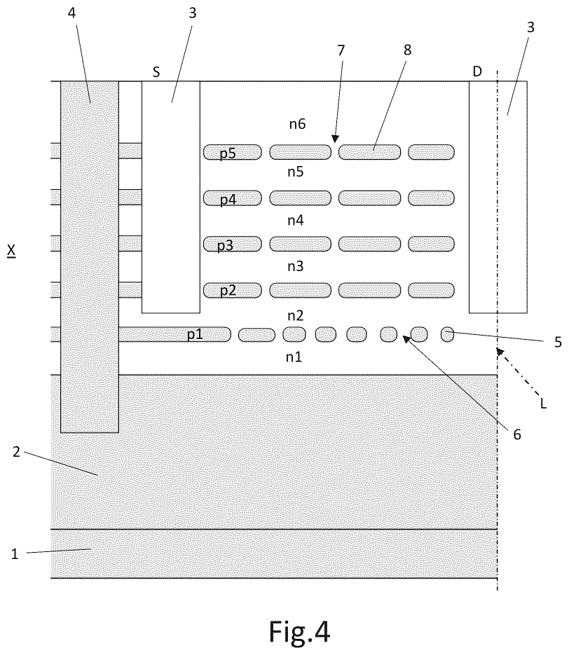

FIG. 4 shows a variation of FIG. 1, where the first layer of first conductivity type p1 is divided into several sub-regions 5. This is done by using a different mask than in FIG. 1. Here the length of the sub-regions 5 should be longer towards the source S (left in figure) and the distances 6 between the sub-regions should be longer towards the drain D (right in figure). This will create a gradient in the average amount of doping with more doping of the first conductivity type towards the source side S and less towards the drain side D. The reason for this is not to get more current as in the previous case. The reason is to increase the breakdown voltage by making the electric field more uniform. Near breakdown voltage the drain D trench 3 is at high voltage, and the source S trench 3 and the substrate are connected to ground. This means that the electric field is lateral in the area between the source S and drain D trenches and the electric field is vertical between the bottom of the drain D trench 3 and the substrate 1. This means that the field turns 90 degrees in the area where p1 is located. Normally this means that the electric field is increased near the rightmost tip of p1 close to the drain trench. This increase in electric field lowers the breakdown voltage. By introducing the gradient in the p1-layer the peak in electric field is suppressed and hence a higher breakdown voltage is obtained.

In the drawings the device according to the invention has been described when the first conductivity type is p-type, and the second conductivity type is n-type. However, the device according to the invention can also be implemented so that the first conductivity type is n-type, and the second conductivity type is p-type.

1. A semiconductor device, comprising:
a substrate of a first conductivity type that is a base for the semiconductor device;
a high voltage junction field effect transistor, JFET, over the substrate, wherein the JFET comprising a plurality of parallel conductive layers the JFET being isolated with a deep polycrystalline trench of a first conductivity type on a source side of the JFET;
a first conductive layer of the second conductivity type of the parallel conductive layers stretching over the substrate;
wherein on top of the first conductive layer of the second conductivity type is arranged a plurality of layers forming the parallel conductive layers with channels formed by a plurality of doped epitaxial layers of the second conductivity type with a plurality of gate layers of the first conductivity type on both sides thereof;
wherein,
at least one conductive layer of the first conductivity type above a lowermost conductive layer of the first conductive type is comprised of consecutive regions with different lengths and distances between each of the regions and the deep polycrystalline trenches of the second conductivity type.

2. A semiconductor device according to claim 1, wherein
two or more of the conductive layers of the first conductivity type above a lowermost conductive layer of the first conductive type are comprised of consecutive regions with different lengths and distances between each of the regions and the deep polycrystalline trenches of the second conductivity type.

3. A semiconductor device according to claim 1, wherein
the number and consequently the lengths of the consecutive regions in the conductive layers of the first conductivity type above the lowermost conductive layer of the first conductive type differ between neighboring layers so that openings created by the distances between the regions are displaced in relation to each other.

4. A semiconductor device according to claim 1, wherein
two not-neighboring conductive layers of the first conductivity type above the lowermost conductive layer of the first conductive type are consecutive layers stretching between the deep polycrystalline trenches of the second conductivity type.

5. A semiconductor device according to claim 1, wherein
the lowermost layer of the first conductivity type is arranged in the form of consecutive dots with different lengths and distances between deep polycrystalline trenches of the second conductivity type under the JFET.

6. A semiconductor device according to claim 1, wherein
a further isolated region is arranged over the substrate, comprising logics and analogue control functions, isolated with deep polycrystalline trenches of the first conductivity type on both sides thereof.

7. A semiconductor device according to claim 1, wherein
the first conductivity type is p-type, and the second conductivity type is n-type.

8. A semiconductor device according to claim 1, wherein
the first conductivity type is n-type, and the second conductivity type is p-type.

9. A semiconductor device according to claim 2, wherein
the number and consequently the lengths of the consecutive regions in the conductive layers of the first conductivity type above the lowermost conductive layer of the first conductive type differ between neighboring layers so that openings created by the distances between the regions are displaced in relation to each other.

10. A semiconductor device according to claim 2, wherein
two not-neighboring conductive layers of the first conductivity type above the lowermost conductive layer of the first conductive type are consecutive layers stretching between the deep polycrystalline trenches of the second conductivity type.

11. A semiconductor device according to claim 3, wherein
two not-neighboring conductive layers of the first conductivity type above the lowermost conductive layer of the first conductive type are consecutive layers stretching between the deep polycrystalline trenches of the second conductivity type.

12. A semiconductor device according to claim 2, wherein
the lowermost layer of the first conductivity type is arranged in the form of consecutive dots with different lengths and distances between deep polycrystalline trenches of the second conductivity type under the JFET.

13. A semiconductor device according to claim 3, wherein
the lowermost layer of the first conductivity type is arranged in the form of consecutive dots with different lengths and distances between deep polycrystalline trenches of the second conductivity type under the JFET.

14. A semiconductor device according to claim 4, wherein
the lowermost layer of the first conductivity type is arranged in the form of consecutive dots with different lengths and distances between deep polycrystalline trenches of the second conductivity type under the JFET.

15. A semiconductor device according to claim 2, wherein
a further isolated region is arranged over the substrate, comprising logics and analogue control functions, isolated with deep polycrystalline trenches of the first conductivity type on both sides thereof.

16. A semiconductor device according to claim 3, wherein
a further isolated region is arranged over the substrate, comprising logics and analogue control functions, isolated with deep polycrystalline trenches of the first conductivity type on both sides thereof.

17. A semiconductor device according to claim 4, wherein
a further isolated region is arranged over the substrate, comprising logics and analogue control functions, isolated with deep polycrystalline trenches of the first conductivity type on both sides thereof.

18. A semiconductor device according to claim 5, wherein
a further isolated region is arranged over the substrate, comprising logics and analogue control functions, isolated with deep polycrystalline trenches of the first conductivity type on both sides thereof.

19. A semiconductor device according to claim 2, wherein
the first conductivity type is p-type, and the second conductivity type is n-type.

20. A semiconductor device according to claim 3, wherein
the first conductivity type is p-type, and the second conductivity type is n-type.
